(19) United States
(12) Patent Application Publication
(10) Pub. No.: US 2025/0331188 A1
(43) Pub. Date: Oct. 23, 2025

(54) SEMICONDUCTOR DEVICE, MANUFACTURING METHOD, AND MEMORY SYSTEM

(71) Applicant: Yangtze Memory Technologies Co., Ltd., Wuhan (CN)

(72) Inventors: Tingting GAO, Wuhan (CN); Kun ZHANG, Wuhan (CN); Wenxi ZHOU, Wuhan (CN); Zhiliang XIA, Wuhan (CN); Zongliang HUO, Wuhan (CN)

(21) Appl. No.: 18/890,463

(22) Filed: Sep. 19, 2024

(30) Foreign Application Priority Data
Apr. 17, 2024 (CN) 202410469729.7

(51) Int. Cl. H10B 51/20; H10B 51/30

(52) U.S. Cl. CPC H10B 51/20; H10B 51/30

(57) ABSTRACT

Semiconductor devices, manufacturing methods, and memory systems are provided. In one aspect, a semiconductor device includes: a stack structure including interlayer insulation layers and conductive layers stacked alternately along a first direction and a channel structure penetrating through the stack structure along the first direction. The channel structure includes a storage function layer and a channel layer. Along a second direction perpendicular to the first direction, the storage function layer is between the interlayer insulation layers and the conductive layers stacked alternately and the channel layer. The storage function layer includes a ferroelectric material layer.

### CROSS-REFERENCE TO RELATED APPLICATIONS

This application claims the benefit of priority to Chinese Patent Application No. 202410469729.7, filed on Apr. 17, 2024, the disclosure of which is hereby incorporated by reference in its entirety.

### TECHNICAL FIELD

Examples of the present disclosure relate to the technical field of semiconductors, and in particular to a semiconductor device, a manufacturing method, and a memory system.

### BACKGROUND

With the development of semiconductor processes, the feature size of semiconductor devices is reduced progressively, and the level of integration is increased increasingly. However, as the feature size of semiconductor devices approaches the lower limit of the process, the manufacturing process and manufacturing technique of semiconductor devices become increasingly challenging. Accordingly, it is difficult to continue the increase in the density of memory cells in semiconductor devices, imposing a serious challenge to the industry of semiconductor memories.

### SUMMARY

In view of this, examples of the present disclosure provide a semiconductor device, a manufacturing method, and a memory system.

To achieve the above purpose, the technical solution of the present disclosure is implemented as follows:

In a first aspect, examples of the present disclosure provide a semiconductor device, comprising: a stack structure comprising interlayer insulation layers and conductive layers stacked alternately; and a channel structure penetrating through the stack structure along a stacking direction and comprising a storage function layer and a channel layer, wherein along a direction perpendicular to the stacking direction, the storage function layer is located between the interlayer insulation layers and the conductive layers stacked alternately and the channel layer, and the storage function layer comprises a ferroelectric material layer.

In some examples, the channel structure further comprises a high dielectric constant (high-k) dielectric layer; along the direction perpendicular to the stacking direction, the high-k dielectric layer is located between the interlayer insulation layers and the conductive layers stacked alternately and the ferroelectric material layer.

In some examples, the channel structure further comprises at least one dielectric layer; along the direction perpendicular to the stacking direction, the dielectric layer is located between the ferroelectric material layer and the channel layer, and/or between the interlayer insulation layers and the conductive layers stacked alternately and the ferroelectric material layer.

In some examples, the channel structure further comprises a first dielectric layer located between the high-k dielectric layer and the interlayer insulation layers; along the direction perpendicular to the stacking direction, the high-k dielectric layer is in contact with the conductive layers.

In some examples, the storage function layer further comprises at least one dielectric layer, along the direction perpendicular to the stacking direction, the dielectric layer is located between the interlayer insulation layers and the conductive layers stacked alternately and the ferroelectric material layer; or the dielectric layer is located between the interlayer insulation layers and the conductive layers stacked alternately and the ferroelectric material layer, and between the ferroelectric material layer and the channel layer.

In some examples, each conductive layer comprises a gate layer and an adhesion layer located between the gate layer and at least one of the interlayer insulation layers.

In some examples, the material of the ferroelectric material layer comprises a hafnium-based ferroelectric material, lead zirconate titanate, strontium bismuth tantalate, and zirconium oxide.

In some examples, the high-k dielectric layer has a dielectric constant greater than 5.

In a second aspect, the present application provides a manufacturing method of a semiconductor device, comprising: forming an initial stack structure comprising interlayer insulation layers and sacrificial layers stacked alternately; forming a channel hole penetrating through the initial stack structure; forming a storage function layer and a channel layer sequentially in the channel hole, wherein along a direction perpendicular to a stacking direction, the storage function layer is located between the interlayer insulation layers and the sacrificial layers stacked alternately and the channel layer, and the storage function layer comprises a ferroelectric material layer; and replacing the sacrificial layers with conductive layers.

In some examples, before forming the storage function layer and the channel layer sequentially in the channel hole, the manufacturing method of a semiconductor device further comprises: forming a high dielectric constant (high k) dielectric layer in the channel hole, wherein the high k dielectric layer is in contact with the interlayer insulation layers and the sacrificial layers stacked alternately.

In some examples, the forming the storage function layer in the channel hole comprises: forming a second dielectric layer and the ferroelectric material layer sequentially in the channel hole, so as to form the storage function layer, wherein along the direction perpendicular to the stacking direction, the second dielectric layer is located between the interlayer insulation layers and the sacrificial layers stacked alternately and the ferroelectric material layer.

In some examples, after forming the second dielectric layer and the ferroelectric material layer sequentially in the channel hole, the manufacturing method of a semiconductor device further comprises: forming a third dielectric layer in the channel hole, wherein the third dielectric layer is located between the ferroelectric material layer and the channel layer.

In some examples, the forming the storage function layer in the channel hole comprises: forming the ferroelectric material layer and a third dielectric layer sequentially in the channel hole, so as to form the storage function layer, wherein the third dielectric layer is located between the ferroelectric material layer and the channel layer.

In some examples, before forming the storage function layer and the channel layer sequentially in the channel hole, the manufacturing method of a semiconductor device further comprises: forming a first dielectric layer and a high-k dielectric layer sequentially in the channel hole, wherein along the direction perpendicular to the stacking direction, the first dielectric layer is located between the interlayer insulation layers and the sacrificial layers stacked alternately and the high-k dielectric layer.

In some examples, the replacing the sacrificial layers with the conductive layers comprises: removing the sacrificial layers to form first gaps between a plurality of interlayer insulation layers, wherein the first gaps expose a portion of the first dielectric layer; removing the first dielectric layer exposed in the first gaps, so as to form second gaps; and forming the conductive layers in the second gaps.

In some examples, the replacing the sacrificial layers with the conductive layers comprises: removing the sacrificial layers to form first gaps between a plurality of interlayer insulation layers; and forming the conductive layers in the first gaps.

In some examples, the forming the high-k dielectric layer in the channel hole comprises: forming a high-k dielectric material layer in the channel hole; and annealing the high-k dielectric material layer at a high temperature to form the high-k dielectric layer.

In some examples, after forming the storage function layer and the channel layer sequentially in the channel hole, the manufacturing method of a semiconductor device further comprises: forming a dielectric filling layer in the channel hole to fill the channel hole.

In some examples, the forming the storage function layer in the channel hole comprises: forming the ferroelectric material layer in the channel hole, wherein the material of the ferroelectric material layer comprises a hafnium-based ferroelectric material, lead zirconate titanate, strontium bismuth tantalate, and zirconium oxide.

In some examples, the high-k dielectric layer has a dielectric constant greater than 5.

In third aspect, examples of the present disclosure provide a memory system, comprising: a semiconductor device as described in any one of the above examples; and a controller coupled to the semiconductor device and configured to control the semiconductor device.

Examples of the present disclosure provide a semiconductor device, a manufacturing method, and a memory system. The semiconductor device comprises: a stack structure comprising interlayer insulation layers and conductive layers stacked alternately; and a channel structure penetrating through the stack structure along a stacking direction and comprising a storage function layer and a channel layer, wherein along a direction perpendicular to the stacking direction, the storage function layer is located between the interlayer insulation layers and the conductive layers stacked alternately and the channel layer, and the storage function layer comprises a ferroelectric material layer. In the examples of the present disclosure, the storage function layer of the channel structure comprises the ferroelectric material layer having ferroelectricity that may be configured to store data. Since the ferroelectric material layer with a very small thickness may still have stable ferroelectricity, the storage function layer composed of the ferroelectric material layer has a smaller thickness compared with a storage function layer of an ONO structure, and the size of the channel structure may become smaller. As such, the number of channel structures per unit area arranged on a semiconductor substrate is increased, thereby increasing the storage density.

### BRIEF DESCRIPTION OF THE DRAWINGS

FIG. 1 is a cross-sectional view of a semiconductor device provided by examples of the present disclosure;

FIG. 2 is a local enlarged view I of the semiconductor device provided by examples of the present disclosure;

FIG. 3 is a local enlarged view II of the semiconductor device provided by examples of the present disclosure;

FIG. 4 is a local enlarged view III of the semiconductor device provided by examples of the present disclosure;

FIG. 5 is a local enlarged view IV of the semiconductor device provided by examples of the present disclosure;

FIG. 6 is a local enlarged view V of the semiconductor device provided by examples of the present disclosure;

FIG. 7 is a local enlarged view VI of the semiconductor device provided by examples of the present disclosure;

FIG. 8 is a local enlarged view VII of the semiconductor device provided by examples of the present disclosure;

FIG. 9 is a local enlarged view VIII of the semiconductor device provided by examples of the present disclosure;

FIG. 10 is a flow diagram of a manufacturing method of a semiconductor device provided by examples of the present disclosure;

FIG. 11A to FIG. 11D illustrate a manufacturing method of a semiconductor device provided by examples of the present disclosure;

FIG. 12A to FIG. 12C illustrate another manufacturing method of another semiconductor device provided by examples of the present disclosure; and

FIG. 13 is a block diagram of a memory system provided by examples of the present disclosure.

### DETAILED DESCRIPTION

The technical solutions in implementations of the present disclosure will be described below clearly and completely in conjunction with the implementations and the drawings of the present disclosure. Apparently, the described implementations are merely part, but not all, of the implementations of the present disclosure. All other implementations obtained by those of ordinary skill in the art based on the implementations in the present disclosure without creative work shall fall within the scope of protection of the present disclosure.

In the description below, many particular details are presented to provide a more thorough understanding of the present disclosure. However, it is obvious to a person skilled in the art that the present disclosure may be implemented without one or more of these details. In other examples, in order to avoid confusing with the present disclosure, some technical features well-known in the art are not described; that is, not all features of actual examples are described herein, and well-known functions and structures are not described in detail.

In the drawings, sizes and relative sizes of layers, areas and elements may be exaggerated for clarity. Like reference numerals denote like elements throughout.

It is to be understood that when an element or a layer is referred to as being “on”, “adjacent to”, “connected to”, or “coupled to” other elements or layers, it may be directly on, adjacent to, connected to, or coupled to the other elements or layers, or one or more intervening elements or layers may be present. In contrast, when an element is referred to as being “directly on”, “immediately adjacent to”, “directly connected to”, or “directly coupled to” other elements or layers, no intervening elements or layers are present. It is to be understood that, although the terms first, second, and third, etc., may be used to describe various elements, components, areas, layers and/or portions, these elements, components, areas, layers and/or portions should not be limited by these terms. These terms are only used to distinguish one element, component, area, layer or portion from another element, component, area, layer or portion. Thus, a first element, component, area, layer or portion discussed below may be denoted as a second element, component, area, layer or portion, without departing from the teachings of the present disclosure. When the second element, component, area, layer or portion is discussed, it does not mean that the first element, component, area, layer or portion is necessarily present in the present disclosure.

The spatially relative terms, such as “beneath”, “below”, “lower”, “under”, “above”, and “upper” may be used here for ease of description, to describe a relationship of one element or feature shown in the drawings with other elements or features. It is to be understood that in addition to orientations shown in the drawings, the spatial relationship terms are intended to further comprise different orientations of a device in use and operation. For example, if the device in the drawings is turned over, then an element or a feature described as being “below other elements”, or “under other elements”, or “beneath other elements” will be orientated as being “above” the other elements or features. Thus, the example terms “below” and “beneath” may comprise both upper and lower orientations. The device may be orientated otherwise (rotated by 90 degrees or in other orientations), and the spatial descriptive terms used herein are interpreted accordingly.

The terms used herein are intended to describe the particular examples only, and are not used as limitations to the present disclosure. As used herein, unless otherwise indicated expressly in the context, “a”, “an” and “the” in a singular form are also intended to comprise a plural form. It is also to be understood that terms “composed of” and/or “comprise”, when used in this specification, determine the presence of described features, integers, steps, operations, elements and/or components, but do not preclude the presence or addition of one or more of other features, integers, steps, operations, elements, components, and/or groups. As used herein, the term “and/or” comprises any and all combinations of related items listed.

In order to understand the present disclosure thoroughly, detailed operations and detailed structures will be proposed in the following description to set forth the technical solution of the present disclosure. Detailed descriptions of examples of the present disclosure are as follows. However, the present disclosure may also have other implementations in addition to these detailed descriptions.

With continuous development of the semiconductor technology, there is an increasingly high demand for a storage density of a three-dimensional memory. In one example, a charge barrier layer, a charge trap layer, and a tunneling layer in a Channel Hole (CH) of the three-dimensional memory (3D NAND) form a storage function layer jointly, i.e., a storage function layer of an ONO structure, which is configured to store data. However, the storage function layer of the ONO structure has a complex structure, making it difficult to reduce the thickness thereof. Accordingly, it is difficult to further increase the storage density of the memory.

Therefore, there is an urgent need to provide a semiconductor device for increasing the storage density of the memory.

Examples of the present disclosure provide a semiconductor device, comprising: a stack structure comprising interlayer insulation layers and conductive layers stacked alternately; and a channel structure penetrating through the stack structure along a stacking direction and comprising a storage function layer and a channel layer, wherein along a direction perpendicular to the stacking direction, the storage function layer is located between the interlayer insulation layers and the conductive layers stacked alternately and the channel layer, and the storage function layer comprises a ferroelectric material layer.

Before introducing the semiconductor device and manufacturing method thereof provided by the examples of the present disclosure, directions that may be involved in the examples of the present disclosure are defined first. The stacking direction is defined as a Z direction, an X direction and a Y direction are defined in a plane perpendicular to the Z direction, and the X direction and the Y direction may intersect. In a particular example, the X direction and the Y direction may be perpendicular to each other, so that the X direction, the Y direction and the Z direction are perpendicular to each other pairwise.

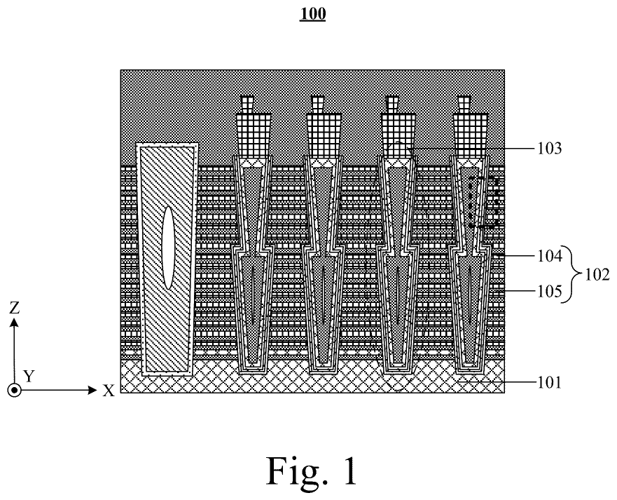

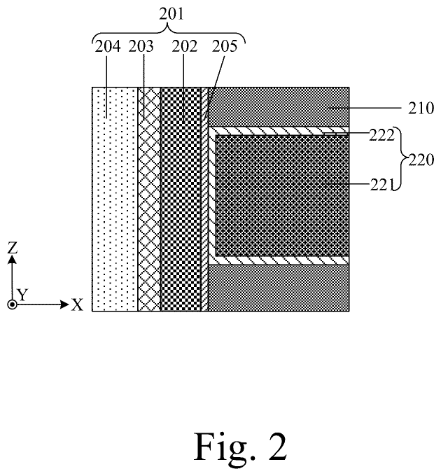

With reference to FIG. 1 and FIG. 2, FIG. 1 is a cross-sectional view of the semiconductor device provided by examples of the present disclosure. FIG. 2 is a local enlarged view I of the semiconductor device provided by examples of the present disclosure.

As shown in FIG. 1, the semiconductor device 100 comprises a semiconductor substrate 101, a stack structure 102 located on the semiconductor substrate 101, and a channel structure 103, wherein the stack structure 102 comprises the interlayer insulation layers 104 and the conductive layers 105 stacked alternately. The channel structure 103 penetrates through the stack structure 102 along the Z direction and extends into the semiconductor substrate 101.

In the examples of the present disclosure, the storage function layer comprises the ferroelectric material layer. In an example, with reference to FIG. 2, FIG. 2 illustrates an enlarged view of a portion in a dashed line box in FIG. 1. As shown in FIG. 2, the channel structure 201 comprises the ferroelectric material layer 202 and the channel layer 203, wherein in a radial direction of a channel, i.e., any direction in a plane where an X axis and a Y axis are located, the ferroelectric material layer 202 is located between the interlayer insulation layers 210 and the conductive layers 220 stacked alternately and the channel layer 203.

In the examples of the present disclosure, the ferroelectric material layer 202 is used as the storage function layer, and the ferroelectricity of the ferroelectric material layer 202 is used for data storage. In an example, when an electric field is applied to the ferroelectric material layer 202, central atoms of the ferroelectric material move under the action of the electric field and reach a stable state; when the action of the electric field is removed, the central atoms of the ferroelectric material remain in original positions, so that the memory has a non-volatile storage characteristic.

In the examples of the present disclosure, the material of the ferroelectric material layer 202 comprises a hafnium-based ferroelectric material, lead zirconate titanate, strontium bismuth tantalate, and zirconium oxide.

The ferroelectric material layer, when used as the storage function layer, has a smaller thickness compared with the storage function layer of the ONO structure, and still has good ferroelectricity. Therefore, in the examples of the present disclosure, forming the storage function layer using the ferroelectric material in place of the storage function layer of the ONO structure in the example may further reduce the thickness of the storage function layer, thereby reducing the size of the channel structure, so that the number of channel structures per unit area is increased and the storage density is increased accordingly. Meanwhile, gate operating voltages of the channel structures formed by storage function layers of different materials are different. In an example, a gate operating voltage of the channel structure formed by the storage function layer comprising the ferroelectric material layer is lower than a gate operating voltage of a channel structure formed by the storage function layer of the ONO structure in the example. Accordingly, in a peripheral circuit, examples of the present disclosure may use more lower-cost low-voltage CMOS transistors to replace at least some of the higher-cost high-voltage CMOS transistors, thereby reducing manufacturing costs greatly.

In the examples of the present disclosure, the material of the channel layer 203 may include, but is not limited to, amorphous silicon, polycrystalline silicon, or monocrystalline silicon.

In the examples of the present disclosure, the channel structure 201 further comprises a dielectric filling layer 204, and the dielectric filling layer 204 may fully fill the channel structure 201 to provide support for the channel structure 201. At this time, in the radial direction of the channel, the channel layer 203 surrounds the dielectric filling layer 204, and the channel layer 203 is located between the dielectric filling layer 204 and the ferroelectric material layer 202. In some examples, the material of the dielectric filling layer 204 includes silicon oxide.

In the examples of the present disclosure, the channel structure further comprises a high dielectric constant (high-k) dielectric layer; along the direction perpendicular to the stacking direction, the high-k dielectric layer is located between the interlayer insulation layers and the conductive layers stacked alternately and the ferroelectric material layer.

As shown in FIG. 2, the channel structure 201 comprises the dielectric filling layer 204, the channel layer 203, the ferroelectric material layer 202, and the high-k dielectric layer 205. Herein, the ferroelectric material layer 202 is used as the storage function layer. Herein, in the radial direction of the channel, the channel layer 203 surrounds the dielectric filling layer 204, the channel layer 203 is located between the dielectric filling layer 204 and the ferroelectric material layer 202, the ferroelectric material layer 202 is located between the channel layer 203 and the high-k dielectric layer 205, and the high-k dielectric layer 205 is located between the interlayer insulation layers 210 and the conductive layers 220 stacked alternately and the ferroelectric material layer 202.

In the examples of the present disclosure, the high-k dielectric layer 205 has a dielectric constant greater than 5.

In the examples of the present disclosure, the material of the high-k dielectric layer 205 includes hafnium oxide (HfO₂), aluminum oxide (Al₂O₃), zirconium oxide (ZrO₂), and hafnium silicon oxynitride (HfSiON).

In the examples of the present disclosure, each conductive layer comprises a gate layer and an adhesion layer located between the gate layer and at least one of the interlayer insulation layers.

As shown in FIG. 2, the conductive layer 220 comprises the gate layer 221 and the adhesion layer 222 located between the gate layer 221 and the at least one of the interlayer insulation layers 210, and the adhesion layer 222 is located between the channel structure 201 and the gate layer 221.

It is to be noted that, in some processes, in order to improve the problem of a gate leakage current, the high-k dielectric layer may be formed as a gate dielectric layer in contact with the conductive layers, i.e., a high-k metal gate structure is formed. However, as it is difficult to reduce the thickness of the storage function layer of the ONO structure in the preceding example, it is thus difficult to integrate the high-k dielectric layer in that channel structure. Therefore, the high-k dielectric layer is typically formed between interlayer insulation layers in a gate replacement process, forming the conductive layer together with the gate layer. With reference to FIG. 2, in the examples of the present disclosure, using the ferroelectric material layer as the storage function layer may ensure that the high-k dielectric layer is integrated in the channel structure without increasing the size of the channel structure. As such, not only the problem of the gate leakage current may be improved, but also the thickness of the conductive layers may be reduced, so that there are more conductive layers contained in the stack structure of a particular height, thereby increasing the storage density effectively.

In the examples of the present disclosure, the material of the gate layer 221 includes, but is not limited to, a combination of one or more of tungsten (W), cobalt (Co), copper (Cu), aluminum (Al), polycrystalline silicon, doped silicon, and silicide, or may be other suitable materials. The adhesion layer is configured to improve adhesion between the gate layer and other structures in contact therewith, so as to improve the reliability of the semiconductor structure. The adhesion layer 222 may be a conductive material including, but not limited to at least one of: metals (such as titanium (Ti), tantalum (Ta), chromium (Cr), and tungsten (W)), metal compounds (such as titanium nitride (TiNₓ), tantalum nitride (TaNₓ), chromium nitride (CrNₓ), and tungsten nitride (WNₓ)), and metal alloys (such as TiSiₓN_{y}, TaSiₓN_{y}, CrSiₓN_{y}, and WSiₓN_{y}). In practical situations, the particular material of the adhesion layer 222 may be determined based on the material of the gate layer 221, so as to improve an overall conduction efficiency of the gate layer 221 and the adhesion layer 222.

In the examples of the present disclosure, the interlayer insulation layers 210 may comprise an insulation material including, but not limited to, silicon oxide (SiO₂), silicon nitride (SiN), silicon oxynitride (SiNₓO_{y}), or other suitable materials.

In the examples of the present disclosure, the channel structure further comprises at least one dielectric layer; along the direction perpendicular to the stacking direction, the dielectric layer is located between the ferroelectric material layer and the channel layer, and/or between the interlayer insulation layers and the conductive layers stacked alternately and the ferroelectric material layer.

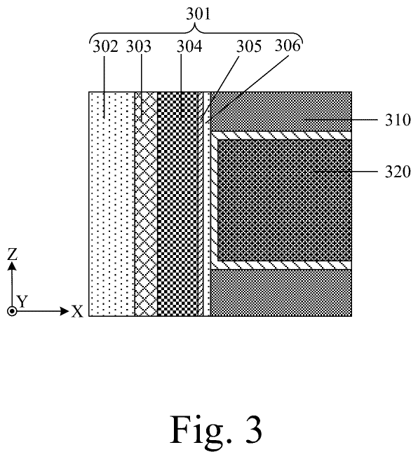

With reference to FIG. 3, FIG. 3 is a local enlarged view II of the semiconductor device provided by examples of the present disclosure.

As shown in FIG. 3, the channel structure 301 comprises the dielectric filling layer 302, the channel layer 303, the ferroelectric material layer 304, the high-k dielectric layer 305, and the dielectric layer 306. The ferroelectric material layer 304 is used as the storage function layer. Herein, in the radial direction of the channel, the channel layer 303 surrounds the dielectric filling layer 302, the channel layer 303 is located between the dielectric filling layer 302 and the ferroelectric material layer 304, the ferroelectric material layer 304 is located between the channel layer 303 and the high-k dielectric layer 305, the high-k dielectric layer 305 is located between the ferroelectric material layer 304 and the dielectric layer 306, and the dielectric layer 306 is located between the interlayer insulation layers 310 and the conductive layers 320 stacked alternately and the high-k dielectric layer 305. The dielectric layer 306 and the high-k dielectric layer 305 form the gate dielectric layer jointly, thereby reducing the gate leakage current.

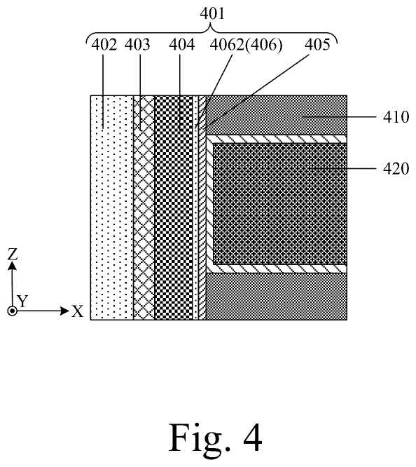

With reference to FIG. 4, FIG. 4 is a local enlarged view III of the semiconductor device provided by examples of the present disclosure.

As shown in FIG. 4, the channel structure 401 comprises the dielectric filling layer 402, the channel layer 403, the ferroelectric material layer 404, the high-k dielectric layer 405, and the dielectric layer 406. Here, the dielectric layer 406 located between the interlayer insulation layers 410 and the conductive layers 420 stacked alternately and the ferroelectric material layer 404 is defined as a second dielectric layer 4062. The ferroelectric material layer 404 and the second dielectric layer 4062 form the storage function layer jointly. Herein, in the radial direction of the channel, the channel layer 403 surrounds the dielectric filling layer 402, the channel layer 403 is located between the dielectric filling layer 402 and the ferroelectric material layer 404, the ferroelectric material layer 404 is located between the channel layer 403 and the second dielectric layer 4062, the second dielectric layer 4062 is located between the ferroelectric material layer 404 and the high-k dielectric layer 405, and the high-k dielectric layer 405 is located between the interlayer insulation layers 410 and the conductive layers 420 stacked alternately and the second dielectric layer 4062. In FIG. 4, the second dielectric layer 4062 may serve as an interface buffer layer to improve a bonding force between the ferroelectric material layer 404 and the high-k dielectric layer 405, and meanwhile, the second dielectric layer 4062 may release a stress generated during generation of the ferroelectric material layer, which is beneficial to improve the quality of a subsequent process. Moreover, the ferroelectric material in the ferroelectric material layer 404 may be prevented from diffusing into the high-k dielectric layer 405.

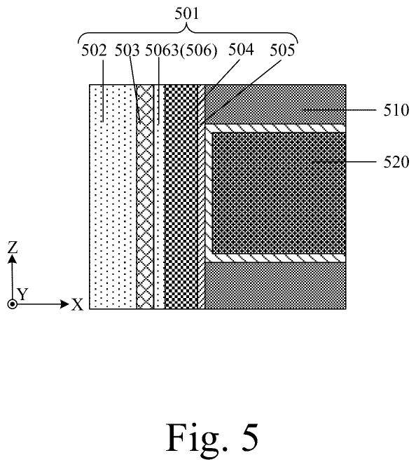

With reference to FIG. 5, FIG. 5 is a local enlarged view IV of the semiconductor device provided by examples of the present disclosure.

As shown in FIG. 5, the channel structure 501 comprises the dielectric filling layer 502, the channel layer 503, the ferroelectric material layer 504, the high-k dielectric layer 505, and the dielectric layer 506. Here, the dielectric layer 506 located between the channel layer 503 and the ferroelectric material layer 504 is defined as a third dielectric layer 5063, and the ferroelectric material layer 504 and the third dielectric layer 5063 form the storage function layer jointly. Herein, in the radial direction of the channel, the channel layer 503 surrounds the dielectric filling layer 502, the channel layer 503 is located between the dielectric filling layer 502 and the third dielectric layer 5063, the third dielectric layer 5063 is located between the channel layer 503 and the ferroelectric material layer 504, the ferroelectric material layer 504 is located between the third dielectric layer 5063 and the high-k dielectric layer 505, and the high-k dielectric layer 505 is located between the interlayer insulation layers 510 and the conductive layers 520 stacked alternately and the ferroelectric material layer 504. In FIG. 5, the third dielectric layer 5063 may serve as an interface buffer layer to improve a bonding force between the channel layer 503 and the ferroelectric material layer 504.

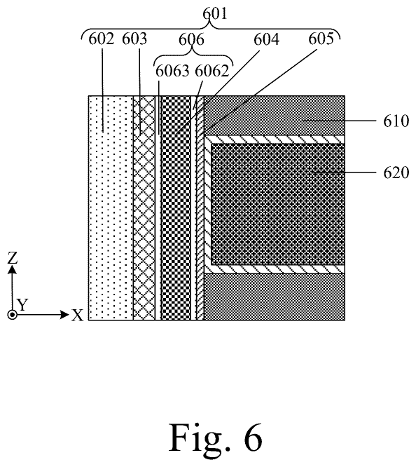

With reference to FIG. 6, FIG. 6 is a local enlarged view V of the semiconductor device provided by examples of the present disclosure.

As shown in FIG. 6, the channel structure 601 comprises the dielectric filling layer 602, the channel layer 603, the ferroelectric material layer 604, the high-k dielectric layer 605, and the dielectric layer 606. The dielectric layer 606 comprises the second dielectric layer 6062 and the third dielectric layer 6063. The ferroelectric material layer 604, the second dielectric layer 6062, and the third dielectric layer 6063 form the storage function layer jointly. Herein, in the radial direction of the channel, the channel layer 603 surrounds the dielectric filling layer 602, the channel layer 603 is located between the dielectric filling layer 602 and the third dielectric layer 6063, the third dielectric layer 6063 is located between the channel layer 603 and the ferroelectric material layer 604, the ferroelectric material layer 604 is located between the third dielectric layer 6063 and the second dielectric layer 6062, the second dielectric layer 6062 is located between the ferroelectric material layer 604 and the high-k dielectric layer 605, and the high-k dielectric layer 605 is located between the interlayer insulation layers 610 and the conductive layers 620 stacked alternately and the second dielectric layer 6062. Here, the third dielectric layer 6063 and the second dielectric layer 6062 may serve as interface buffer layers to prevent the ferroelectric material of the ferroelectric material layer 604 located between the third dielectric layer 6063 and the second dielectric layer 6062 from diffusing into the channel layer 603 and the high-k dielectric layer 605 respectively.

In the examples of the present disclosure, the material of the dielectric layer 606 includes silicon oxide, silicon oxynitride, silicon nitride, or combinations thereof.

In the examples of the present disclosure, the channel structure further comprises a first dielectric layer located between the high-k dielectric layer and the interlayer insulation layers; along the direction perpendicular to the stacking direction, the high-k dielectric layer is in contact with the conductive layers.

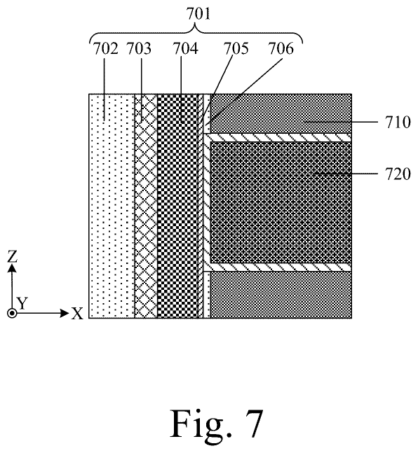

With reference to FIG. 7, FIG. 7 is a local enlarged view VI of the semiconductor device provided by examples of the present disclosure.

As shown in FIG. 7, the channel structure 701 comprises the dielectric filling layer 702, the channel layer 703, the ferroelectric material layer 704, the high-k dielectric layer 705, and the first dielectric layer 706. Herein, the ferroelectric material layer 704 is used as the storage function layer. Herein, in the radial direction of the channel, the channel layer 703 surrounds the dielectric filling layer 702, the channel layer 703 is located between the dielectric filling layer 702 and the ferroelectric material layer 704, the ferroelectric material layer 704 is located between the channel layer 703 and the high-k dielectric layer 705, and the first dielectric layer 706 is located between the high-k dielectric layer 705 and the interlayer insulation layers 710. It is to be noted that the high-k dielectric layer 705 is in contact with the conductive layers 720, and the high-k dielectric layer 705 is not in contact with the interlayer insulation layers 710.

In the examples of the present disclosure, there may be no obvious interface between the first dielectric layer 706 and the interlayer insulation layers 710.

In the examples of the present disclosure, the material of the first dielectric layer 706 includes silicon oxide, silicon oxynitride, silicon nitride, or combinations thereof.

In some examples of the present disclosure, the channel structure may comprise no high-k dielectric layer. In the examples of the present disclosure, the storage function layer further comprises at least one dielectric layer, along the direction perpendicular to the stacking direction, the dielectric layer is located between the interlayer insulation layers and the conductive layers stacked alternately and the ferroelectric material layer; or the dielectric layer is located between the interlayer insulation layers and the conductive layers stacked alternately and the ferroelectric material layer, and between the ferroelectric material layer and the channel layer.

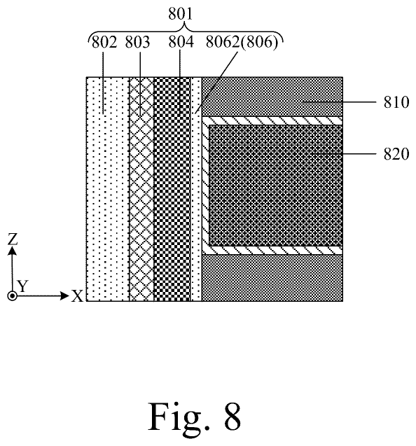

With reference to FIG. 8, FIG. 8 is a local enlarged view VII of the semiconductor device provided by examples of the present disclosure.

As shown in FIG. 8, the channel structure 801 comprises the dielectric filling layer 802, the channel layer 803, the ferroelectric material layer 804, and the dielectric layer 806. Here, the dielectric layer 806 is the second dielectric layer 8062. The ferroelectric material layer 804 and the second dielectric layer 8062 form the storage function layer jointly. Herein, in the radial direction of the channel, the channel layer 803 surrounds the dielectric filling layer 802, the channel layer 803 is located between the dielectric filling layer 802 and the ferroelectric material layer 804, the ferroelectric material layer 804 is located between the channel layer 803 and the second dielectric layer 8062, and the second dielectric layer 8062 is located between the interlayer insulation layers 810 and the conductive layers 820 stacked alternately and the ferroelectric material layer 804. Here, the second dielectric layer 8062 may serve as an interface buffer layer to improve a bonding force between the interlayer insulation layers 810 and the conductive layers 820 stacked alternately and the ferroelectric material layer 804.

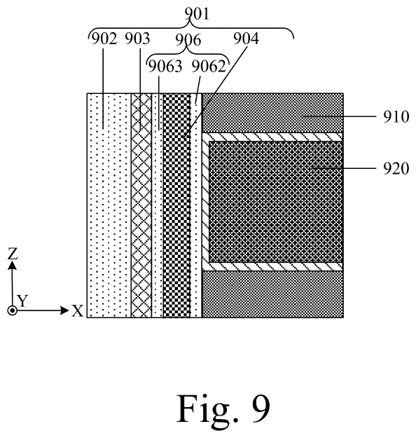

With reference to FIG. 9, FIG. 9 is a local enlarged view VIII of the semiconductor device provided by examples of the present disclosure.

As shown in FIG. 9, the channel structure 901 comprises the dielectric filling layer 902, the channel layer 903, the ferroelectric material layer 904, and the dielectric layer 906. Herein, the dielectric layer 906 comprises the second dielectric layer 9062 and the third dielectric layer 9063. The ferroelectric material layer 904, the second dielectric layer 9062, and the third dielectric layer 9063 form the storage function layer jointly. Herein, in the radial direction of the channel, the channel layer 903 surrounds the dielectric filling layer 902, the channel layer 903 is located between the dielectric filling layer 902 and the third dielectric layer 9063, the third dielectric layer 9063 is located between the channel layer 903 and the ferroelectric material layer 904, the ferroelectric material layer 904 is located between the third dielectric layer 9063 and the second dielectric layer 9062, and the second dielectric layer 9062 is located between the interlayer insulation layers 910 and the conductive layers 920 stacked alternately and the ferroelectric material layer 904. Here, the third dielectric layer 9063 and the second dielectric layer 9062 may serve as interface buffer layers to prevent the ferroelectric material of the ferroelectric material layer 904 located between the third dielectric layer 9063 and the second dielectric layer 9062 from diffusing into the channel layer 903, the conductive layers 920, and the interlayer insulation layers 910 respectively.

In the examples of the present disclosure, since the gate operating voltage of the channel structure formed by the storage function layer comprising the ferroelectric material layer is low, the gate leakage current of the semiconductor device in FIG. 8 and FIG. 9 may be controlled as being in a normal range even if there is no high-k dielectric layer in the channel structure.

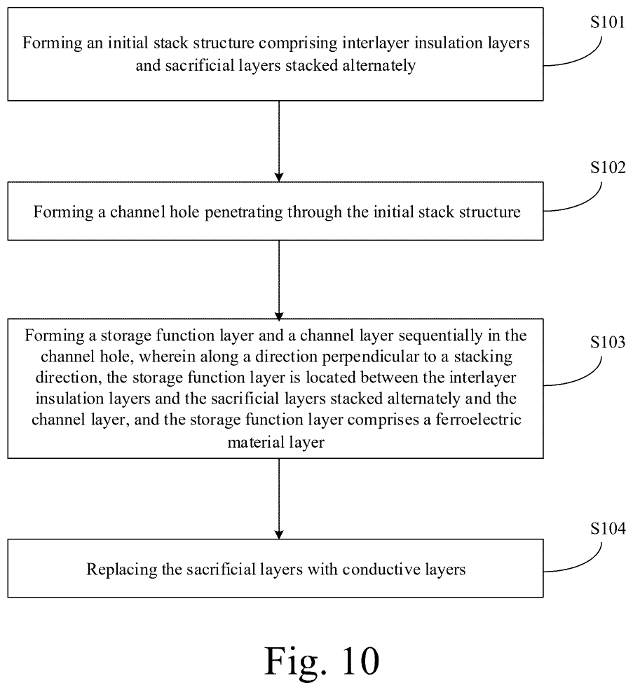

With reference to FIG. 10, FIG. 10 is a flow diagram of a manufacturing method of a semiconductor device provided by examples of the present disclosure.

As shown in FIG. 10, examples of the present disclosure further provide the manufacturing method of a semiconductor device, comprising:

Operation S101: forming an initial stack structure comprising interlayer insulation layers and sacrificial layers stacked alternately.

Operation S102: forming a channel hole penetrating through the initial stack structure.

Operation S103: forming a storage function layer and a channel layer sequentially in the channel hole, wherein along a direction perpendicular to a stacking direction, the storage function layer is located between the interlayer insulation layers and the sacrificial layers stacked alternately and the channel layer, and the storage function layer comprises a ferroelectric material layer.

Operation S104: replacing the sacrificial layers with conductive layers.

In the examples of the present disclosure, the interlayer insulation layers, the sacrificial layers, and the storage function layer and the channel layer in the channel hole each may be formed by one or more deposition processes. Herein, the deposition process may include, but is not limited to, Physical Vapor Deposition (PVD), Chemical Vapor Deposition (CVD), Atomic Layer Deposition (ALD), or any combinations thereof.

In the examples of the present disclosure, a process for forming the channel hole penetrating through the initial stack structure includes a dry etching process.

In some examples of the present disclosure, before forming the storage function layer and the channel layer sequentially in the channel hole, the manufacturing method of a semiconductor device further comprises: forming a high dielectric constant (high k) dielectric layer in the channel hole, wherein the high k dielectric layer is in contact with the interlayer insulation layers and the sacrificial layers stacked alternately.

In an example, with reference to FIG. 2, the high-k dielectric layer 205, the ferroelectric material layer 202, and the channel layer 203 are formed in the channel hole sequentially. Herein, the high-k dielectric layer 205 is in contact with the interlayer insulation layers 210 and the sacrificial layers stacked alternately.

In the examples of the present disclosure, the high-k dielectric layer 205 has a dielectric constant greater than 5.

In the examples of the present disclosure, the forming the high-k dielectric layer in the channel hole comprises: forming a high-k dielectric material layer in the channel hole; and annealing the high-k dielectric material layer at a high temperature to form the high-k dielectric layer.

With reference to FIG. 2, in the examples of the present disclosure, by forming the high-k dielectric layer 205 with a higher process temperature in the channel hole followed by forming the ferroelectric material layer 202 with a lower process temperature may prevent the ferroelectric material layer 202 from being affected by the high temperature process of forming the high-k dielectric layer 205, thereby ensuring that the structure of the ferroelectric material layer 202 is not damaged.

In the examples of the present disclosure, the forming the storage function layer in the channel hole comprises: forming a second dielectric layer and the ferroelectric material layer sequentially in the channel hole, so as to form the storage function layer, wherein along the direction perpendicular to the stacking direction, the second dielectric layer is located between the interlayer insulation layers and the sacrificial layers stacked alternately and the ferroelectric material layer.

In an example, reference is made to FIG. 4 or FIG. 8. In FIG. 4, the high-k dielectric layer 405, the second dielectric layer 4062, the ferroelectric material layer 404, and the channel layer 403 are formed in the channel hole sequentially. Herein, the second dielectric layer 4062 and the ferroelectric material layer 404 form the storage function layer jointly. In the radial direction of the channel, the second dielectric layer 4062 is located between the ferroelectric material layer 404 and the high-k dielectric layer 405. In FIG. 8, the second dielectric layer 8062, the ferroelectric material layer 804, and the channel layer 803 are formed in the channel hole sequentially. Herein, the second dielectric layer 8062 and the ferroelectric material layer 804 form the storage function layer jointly. In the radial direction of the channel, the second dielectric layer 8062 is located between the interlayer insulation layers 810 and the sacrificial layers stacked alternately and the ferroelectric material layer 804.

In the examples of the present disclosure, after forming the second dielectric layer and the ferroelectric material layer sequentially in the channel hole, the manufacturing method of a semiconductor device further comprises: forming a third dielectric layer in the channel hole, wherein the third dielectric layer is located between the ferroelectric material layer and the channel layer.

In an example, reference is made to FIG. 6 or FIG. 9. In FIG. 6, the high-k dielectric layer 605, the second dielectric layer 6062, the ferroelectric material layer 604, the third dielectric layer 6063, and the channel layer 603 are formed in the channel hole sequentially. Herein, the second dielectric layer 6062, the third dielectric layer 6063, and the ferroelectric material layer 604 form the storage function layer jointly. In the radial direction of the channel, the third dielectric layer 6063 is located between the ferroelectric material layer 604 and the channel layer 603. In FIG. 9, the second dielectric layer 9062, the ferroelectric material layer 904, the third dielectric layer 9063, and the channel layer 903 are formed in the channel hole sequentially. Herein, the second dielectric layer 9062, the third dielectric layer 9063, and the ferroelectric material layer 904 form the storage function layer jointly. In the radial direction of the channel, the third dielectric layer 9063 is located between the ferroelectric material layer 904 and the channel layer 903.

In the examples of the present disclosure, the forming the storage function layer in the channel hole comprises: forming the ferroelectric material layer and a third dielectric layer sequentially in the channel hole, so as to form the storage function layer, wherein the third dielectric layer is located between the ferroelectric material layer and the channel layer.

With reference to FIG. 5, the high-k dielectric layer 505, the ferroelectric material layer 504, the third dielectric layer 5063, and the channel layer 503 are formed in the channel hole sequentially. Herein, the third dielectric layer 5063 and the ferroelectric material layer 504 form the storage function layer jointly. In the radial direction of the channel, the third dielectric layer 5063 is located between the ferroelectric material layer 504 and the channel layer 503.

In some other examples of the present disclosure, before forming the storage function layer and the channel layer sequentially in the channel hole, the manufacturing method of a semiconductor device further comprises: forming a first dielectric layer and a high-k dielectric layer sequentially in the channel hole, wherein along the direction perpendicular to the stacking direction, the first dielectric layer is located between the interlayer insulation layers and the sacrificial layers stacked alternately and the high-k dielectric layer.

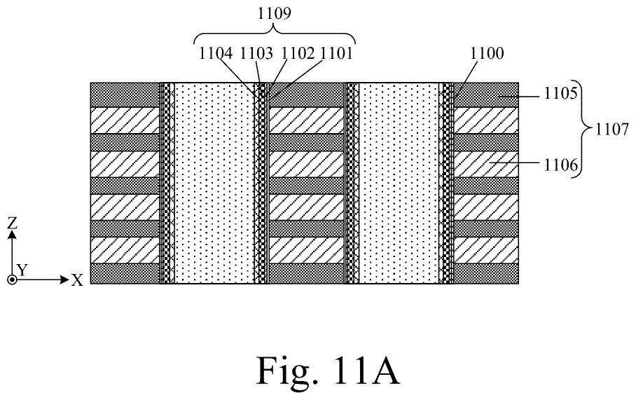

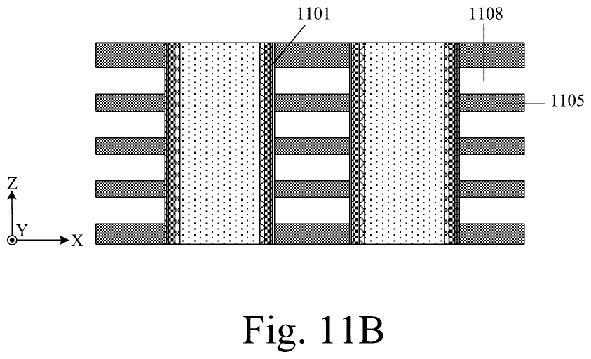

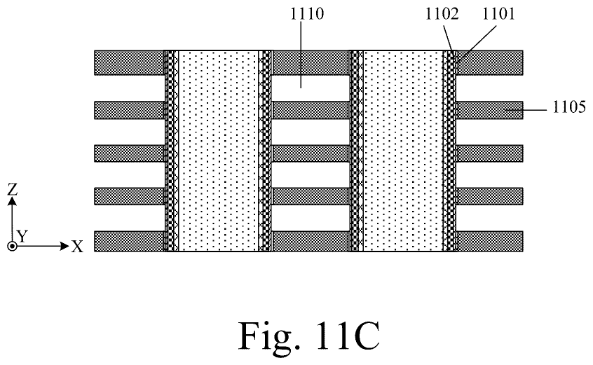

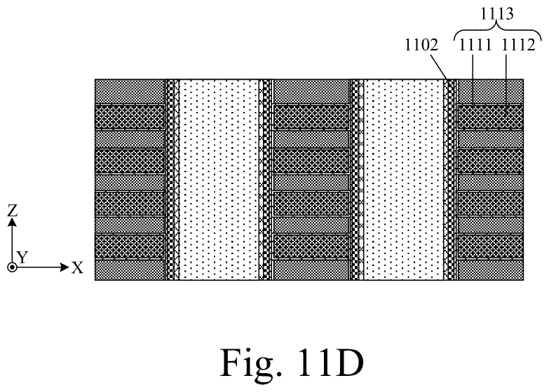

With reference to FIG. 11A to FIG. 11D, FIG. 11A to FIG. 11D illustrate a manufacturing method of a semiconductor device provided by examples of the present disclosure.

As shown in FIG. 11A, the initial stack structure 1107 in which the interlayer insulation layers 1105 and the sacrificial layers 1106 are stacked alternately is formed on the semiconductor substrate (not shown in the figure). The channel hole 1100 penetrating through the initial stack structure 1107 is formed by etching and extends into the semiconductor substrate. The first dielectric layer 1101, the high-k dielectric layer 1102, the ferroelectric material layer 1103, and the channel layer 1104 are formed in the channel hole 1100 sequentially. Herein, the ferroelectric material layer 1103 is the storage function layer. In the radial direction of the channel, the first dielectric layer 1101 is located between the interlayer insulation layers 1105 and the sacrificial layers 1106 stacked alternately and the high-k dielectric layer 1102.

In an example of the present disclosure, the replacing the sacrificial layers with the conductive layers comprises: removing the sacrificial layers to form first gaps between a plurality of interlayer insulation layers, wherein the first gaps expose a portion of the first dielectric layer; removing the first dielectric layer exposed in the first gaps, so as to form second gaps; and forming the conductive layers in the second gaps.

As shown in FIG. 11B, the sacrificial layers 1106 in the initial stack structure 1107 are removed using a wet etching process, so as to form the first gaps 1108 between a plurality of interlayer insulation layers 1105. At this time, a portion of a side face of the first dielectric layer 1101 is exposed in the first gaps 1108.

In the examples of the present disclosure, the first dielectric layer 1101 may serve as a barrier layer to protect the channel structure 1109 from being damaged during the etching process of removing the sacrificial layers 1106.

As shown in FIG. 11C, the portion of the first dielectric layer 1101 exposed in the first gaps 1108 is removed using an etching process, so as to form the second gaps 1110. At this time, a portion of a side face of the high-k dielectric layer 1102 is exposed in the second gaps 1110. In other words, the first dielectric layer 1101 is removed partially, and only a portion of the first dielectric layer 1101 that is located between the high-k dielectric layer 1102 and the interlayer insulation layers 1105 is retained.

As shown in FIG. 11D, the adhesion layer 1111 and the gate layer 1112 are formed sequentially in the second gaps using a deposition process, so as to form the conductive layers 1113. At this time, the gate replacement process is completed. It is to be noted that the adhesion layer 1111 is in contact with a portion of the high-k dielectric layer 1102 at this time, and the gate layer 1112, the adhesion layer 1111, and the high-k dielectric layer 1102 form the high-k metal gate structure jointly.

In another example of the present disclosure, the replacing the sacrificial layers with the conductive layers comprises: removing the sacrificial layers to form first gaps between a plurality of interlayer insulation layers; and forming the conductive layers in the first gaps.

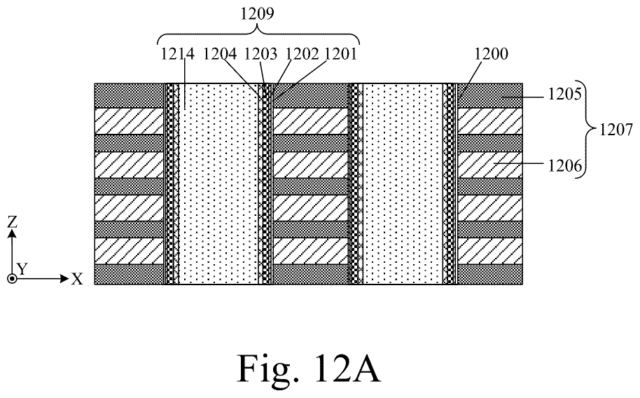

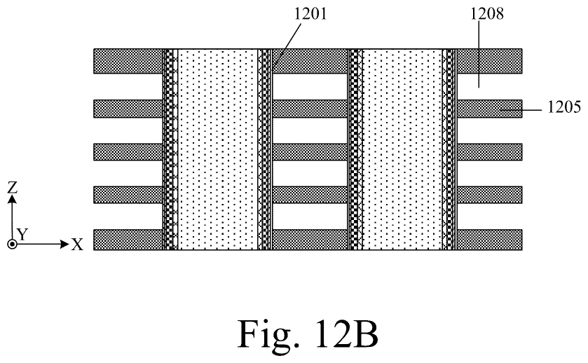

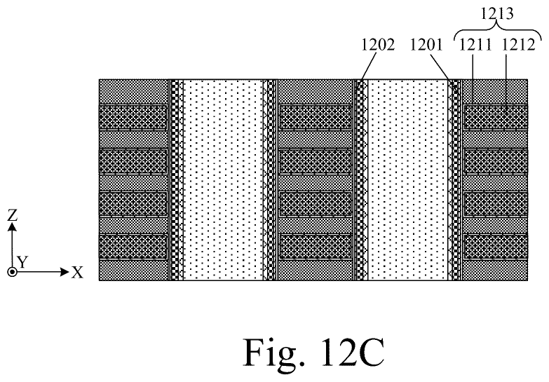

With reference to FIG. 12A to FIG. 12C, FIG. 12A to FIG. 12C illustrate another manufacturing method of a semiconductor device provided by examples of the present disclosure.

As shown in FIG. 12A, the initial stack structure 1207 in which the interlayer insulation layers 1205 and the sacrificial layers 1206 are stacked alternately is formed on the semiconductor substrate (not shown in the figure). The initial stack structure 1207 is etched through to form the channel hole 1200 extending into the semiconductor substrate. The first dielectric layer 1201, the high-k dielectric layer 1202, the ferroelectric material layer 1203, and the channel layer 1204 are formed in the channel hole 1200 sequentially. Herein, the ferroelectric material layer 1203 is the storage function layer. In the radial direction of the channel, the first dielectric layer 1201 is located between the interlayer insulation layers 1205 and the sacrificial layers 1206 stacked alternately and the high-k dielectric layer 1202.

As shown in FIG. 12B, the sacrificial layers 1206 are removed using a wet etching process, so as to form the first gaps 1208 between a plurality of interlayer insulation layers 1205. The first dielectric layer 1201 serves as a barrier layer. At this time, a portion of a side face of the first dielectric layer 1201 is exposed in the first gaps 1208.

As shown in FIG. 12C, the adhesion layer 1211 and the gate layer 1212 are formed sequentially in the first gaps 1208 using a deposition process, so as to form the conductive layers 1213. At this time, the adhesion layer 1211 is in contact with a portion of the first dielectric layer 1201, and the gate layer 1212, the adhesion layer 1211, the first dielectric layer 1201, and the high-k dielectric layer 1202 form the high-k metal gate structure jointly.

It is to be noted that FIG. 11A to FIG. 11D illustrate only the manufacturing method of a semiconductor device corresponding to FIG. 7, and FIG. 12A to FIG. 12C illustrate only the manufacturing method of a semiconductor device corresponding to FIG. 3. It may be understood that the corresponding semiconductor devices in FIG. 2, FIG. 4, FIG. 5, FIG. 6, FIG. 8, and FIG. 9 may also be formed respectively based on the above manufacturing method.

In the examples of the present disclosure, after forming the storage function layer and the channel layer sequentially in the channel hole, the manufacturing method of a semiconductor device further comprises: forming a dielectric filling layer in the channel hole to fill the channel hole.

As shown in FIG. 12A, a filling material is deposited in the channel hole 1200 to form the dielectric filling layer 1214, and the dielectric filling layer 1214 may fully fill the channel hole 1200 to provide support for the channel structure 1209. At this time, the channel layer 1204 surrounds the dielectric filling layer 1214.

In the examples of the present disclosure, the forming the storage function layer in the channel hole comprises: forming the ferroelectric material layer 1203 in the channel hole, wherein the material of the ferroelectric material layer 1203 comprises a hafnium-based ferroelectric material, lead zirconate titanate, strontium bismuth tantalate, and zirconium oxide.

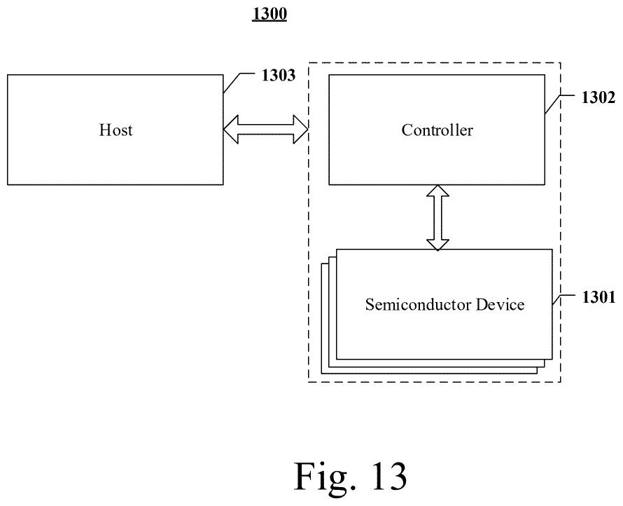

With reference to FIG. 13, FIG. 13 is a block diagram of a memory system provided by examples of the present disclosure.

As shown in FIG. 13, the examples of the present disclosure further provide a memory system 1300 comprising: the semiconductor device 1301 as described in any of the above examples, and a controller 1302 coupled to the semiconductor device 1301, the controller 1302 being configured to control the semiconductor device 1301.

In the examples of the present disclosure, the semiconductor device 1301 may be a memory. The semiconductor device 1301 may also be a part of a memory, that is, the semiconductor device 1301 comprises a memory cell array which may form a memory together with the peripheral circuit.

In the examples of the present disclosure, the memory system 1300 may be integrated into various types of memory apparatuses, e.g., be included in the same package (such as a Universal Flash Storage (UFS) package or an Embedded Multi Media Card (eMMC) package). That is, the memory system may be applied to and packaged into different types of electronic products, e.g., a mobile phone (such as a cellphone), a desktop computer, a tablet computer, a notebook computer, a server, a vehicle apparatus, a gaming console, a printer, a positioning apparatus, a wearable apparatus, a smart sensor, a mobile supply, a Virtual Reality (VR) apparatus, an Augmented Reality (AR) apparatus, or any other suitable electronic apparatuses having memories therein.

In some examples, the controller 1302 is configured to operate in a low duty-cycle environment, such as an SD card, a CF card, a Universal Serial Bus (USB) flash drive, or other media for use in electronic apparatuses, such as a personal computer, a digital camera, or a mobile phone.

In some other examples, the controller 1302 is configured to operate in a high duty-cycle environment, such as an SSD or eMMC which is used as a data memory for mobile apparatuses, such as a smartphone, a tablet computer, and a notebook computer, and an enterprise memory array.

In the examples of the present disclosure, the controller 1302 may be configured to control operations of the memory, such as read, erase, and program operations. The controller 1302 may further be configured to manage various functions with respect to data stored or to be stored in the memory, including, but not limited to, bad-block management, garbage collection, logical-to-physical address conversion, and wear leveling, etc. In some implementations, the controller 1302 is further configured to process an error correction code (ECC) with respect to data read from or written to the memory. The controller 1302 may also perform any other suitable functions, e.g., formatting the memory. The controller 1302 may communicate with an external apparatus (e.g., a host 1303) according to a particular communication protocol. For example, the controller 1302 may communicate with the external apparatus through at least one of various interface protocols, such as a USB protocol, an MMC protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, and a Firewire protocol, etc.

Examples of the present disclosure provide a semiconductor device, a manufacturing method, and a memory system. The semiconductor device comprises: a stack structure comprising interlayer insulation layers and conductive layers stacked alternately; and a channel structure penetrating through the stack structure along a stacking direction and comprising a storage function layer and a channel layer, wherein along a direction perpendicular to the stacking direction, the storage function layer is located between the interlayer insulation layers and the conductive layers stacked alternately and the channel layer, and the storage function layer comprises a ferroelectric material layer. In the examples of the present disclosure, the storage function layer of the channel structure comprises the ferroelectric material layer having ferroelectricity that may be configured to store data. Since the ferroelectric material layer with a very small thickness may still have stable ferroelectricity, the storage function layer composed of the ferroelectric material layer has a smaller thickness compared with a storage function layer of an ONO structure, and the size of the channel structure may become smaller. As such, the number of channel structures per unit area arranged on a semiconductor substrate is increased, thereby increasing the storage density.

It is to be understood that “one example” and “an example” mentioned in the whole specification mean that specific features, structures or characteristics related to the example is included in at least one example of the present disclosure. Therefore, “in one example” or “in an example” appearing at any place throughout specification does not always refer to the same example. In addition, these specific features, structures or characteristics may be combined in one or more examples in any proper manner. It is to be understood that, in various examples of the present disclosure, the sequence number of each process mentioned above does not mean the sequence of execution. The execution sequence of each process should be determined by its functions and internal logic, which should not constitute any limitation on the implementation process of the examples of the present disclosure. The above sequence numbers of the examples of the present disclosure are only for description, and do not represent advantages or disadvantages of the examples.

The above descriptions are merely implementations of the present disclosure, and not intended to limit the patent scope of the present disclosure. Equivalent structure transformation made using the contents of the specification and the drawings of the present disclosure under the inventive concept of the present disclosure, or direct/indirect application to other related technical fields are both encompassed within the patent protection scope of the present disclosure.

What is claimed is:

1. A semiconductor device, comprising:
a stack structure comprising interlayer insulation layers and conductive layers stacked alternately along a first direction; and
a channel structure penetrating through the stack structure along the first direction,
wherein the channel structure comprises a storage function layer and a channel layer, and
wherein, along a second direction perpendicular to the first direction, the storage function layer is between the interlayer insulation layers and the conductive layers stacked alternately and the channel layer, and the storage function layer comprises a ferroelectric material layer.

2. The semiconductor device of claim 1, wherein the channel structure further comprises a high dielectric constant (high-k) dielectric layer, and
wherein, along the second direction perpendicular to the first direction, the high-k dielectric layer is between the interlayer insulation layers and the conductive layers stacked alternately and the ferroelectric material layer.

3. The semiconductor device of claim 2, wherein the channel structure further comprises at least one dielectric layer, and
wherein, along the second direction perpendicular to the first direction, the at least one dielectric layer comprises at least one of
a first dielectric layer between the ferroelectric material layer and the channel layer, or
a second dielectric layer between the interlayer insulation layers and the conductive
layers stacked alternately and the ferroelectric material layer.

4. The semiconductor device of claim 2, wherein the channel structure further comprises a first dielectric layer between the high-k dielectric layer and the interlayer insulation layers, and
wherein, along the second direction perpendicular to the first direction, the high-k dielectric layer is in contact with the conductive layers.

5. The semiconductor device of claim 1, wherein the storage function layer further comprises at least one dielectric layer, and
wherein, along the second direction perpendicular to the first direction, the at least one dielectric layer comprises at least one of:
a first dielectric layer between the interlayer insulation layers and the conductive layers stacked alternately and the ferroelectric material layer, or
a second dielectric layer between the interlayer insulation layers and the conductive
layers stacked alternately and the ferroelectric material layer, and between the ferroelectric material layer and the channel layer.

6. The semiconductor device of claim 1, wherein each of the conductive layers comprises a gate layer and an adhesion layer that is between the gate layer and at least one of the interlayer insulation layers.

7. The semiconductor device of claim 1, wherein a material of the ferroelectric material layer comprises at least one of a hafnium-based ferroelectric material, lead zirconate titanate, strontium bismuth tantalate, or zirconium oxide.

8. The semiconductor device of claim 2, wherein the high-k dielectric layer has a dielectric constant greater than 5.

9. A method of manufacturing a semiconductor device, comprising:
forming an initial stack structure comprising interlayer insulation layers and sacrificial layers stacked alternately along a first direction;
forming a channel hole penetrating through the initial stack structure along the first direction;
forming a storage function layer and a channel layer sequentially in the channel hole, wherein, along a second direction perpendicular to the first direction, the storage function layer is between the interlayer insulation layers and the sacrificial layers stacked alternately and the channel layer, and the storage function layer comprises a ferroelectric material layer; and
replacing the sacrificial layers with conductive layers.

10. The method of claim 9, further comprising:
before forming the storage function layer and the channel layer sequentially in the channel hole, forming a high dielectric constant (high k) dielectric layer in the channel hole,
wherein the high k dielectric layer is in contact with the interlayer insulation layers and the sacrificial layers stacked alternately.

11. The method of of claim 9, wherein forming the storage function layer in the channel hole comprises:
forming a second dielectric layer and the ferroelectric material layer sequentially in the channel hole to form the storage function layer,
wherein, along the second direction perpendicular to the first direction, the second dielectric layer is between the interlayer insulation layers and the sacrificial layers stacked alternately and the ferroelectric material layer.

12. The method of claim 11, further comprising:
after forming the second dielectric layer and the ferroelectric material layer sequentially in the channel hole, forming a third dielectric layer in the channel hole,
wherein, along the second direction perpendicular to the first direction, the third dielectric layer is between the ferroelectric material layer and the channel layer.

13. The method of claim 9, wherein forming the storage function layer in the channel hole comprises:
forming the ferroelectric material layer and a dielectric layer sequentially in the channel hole to form the storage function layer, wherein the dielectric layer is located between the ferroelectric material layer and the channel layer.

14. The method of claim 9, further comprising:
before forming the storage function layer and the channel layer sequentially in the channel hole, forming a first dielectric layer and a high-k dielectric layer sequentially in the channel hole,
wherein, along the second direction perpendicular to the first direction, the first dielectric layer is between the interlayer insulation layers and the sacrificial layers stacked alternately and the high-k dielectric layer.

15. The method of claim 14, wherein replacing the sacrificial layers with the conductive layers comprises:
removing the sacrificial layers to form first gaps between a plurality of interlayer insulation layers, wherein the first gaps expose a portion of the first dielectric layer;
removing the exposed portion of the first dielectric layer in the first gaps to form second gaps; and
forming the conductive layers in the second gaps.

16. The method of claim 9, wherein replacing the sacrificial layers with the conductive layers comprises:
removing the sacrificial layers to form first gaps between a plurality of interlayer insulation layers; and
forming the conductive layers in the first gaps.

17. The method of of claim 10, wherein forming the high-k dielectric layer in the channel hole comprises:
forming a high-k dielectric material layer in the channel hole; and
annealing the high-k dielectric material layer at a high temperature to form the high-k dielectric layer.

18. The method of claim 9, further comprising:
after forming the storage function layer and the channel layer sequentially in the channel hole, forming a dielectric filling layer in the channel hole to fill the channel hole.

19. The method of claim 9, wherein forming the storage function layer in the channel hole comprises:
forming the ferroelectric material layer in the channel hole, wherein a material of the ferroelectric material layer comprises a hafnium-based ferroelectric material, lead zirconate titanate, strontium bismuth tantalate, or zirconium oxide.

20. A memory system, comprising:
a semiconductor device, comprising:
a stack structure comprising interlayer insulation layers and conductive layers stacked alternately along a first direction; and
a channel structure penetrating through the stack structure along the first direction and comprising a storage function layer and a channel layer, wherein, along a second direction perpendicular to the first direction, the storage function layer is between the interlayer insulation layers and the conductive layers stacked alternately and the channel layer, and the storage function layer comprises a ferroelectric material layer; and
a controller coupled to the semiconductor device and configured to control the semiconductor device.
